(19) United States
(12) Patent Application Publication
(10) Pub. No.: US 2026/0346135 A1
(43) Pub. Date: Nov. 5, 2026

(54) SYSTEMS AND METHODS FOR DISPLAY DEVICES IN ELECTRONIC DEVICE CONTROLLERS

(71) Applicant: Microsoft Technology Licensing, LLC, Redmond, WA (US)

(72) Inventors: Kent Allen CAMPBELL, Issaquah, WA (US); Benjamin Uriel Sherrett TEMPLE, Redmond, OR (US); Christopher Erol OGUT, Vancouver, WA (US); Aaron Tyler NELSON, Oaxaca de Juarez (MX); Daniel Calvert CANFIELD, McMinnville, OR (US); Daniel James FAULKNER, Portland, OR (US); Sierra Lila WOLF, Vancouver, WA (US); Isadora Helena PEREIRA COSTA, Seattle, WA (US)

(73) Assignee: Microsoft Technology Licensing, LLC, Redmond, WA (US)

(21) Appl. No.: 19/196,606

(22) Filed: May 1, 2025

(51) Int. Cl. A63F 13/26; A63F 13/24; G06F 3/02; G06F 3/0338

(52) U.S. Cl. CPC A63F 13/26; A63F 13/24; G06F 3/02; G06F 3/0338

(57) ABSTRACT

A display device may include a flexible printed circuit assembly (FPCA) including: a display module located at a first end of the FPCA, and an input device located at a second end of the FPCA opposite the first end. A display device may include a frame supporting the FPCA, wherein the FPCA is wrapped around the frame where the first end of the FPCA and the second end of the FPCA are adjacent to one another.

### BACKGROUND

### Background and Relevant Art

Electronic device controllers allow users to provide directional and button inputs to a video game console or other computing device. Joysticks, thumbsticks, and other directional input sticks can allow for analog or digital directional inputs with the electronic device controller. Face buttons, directional input pads, and triggers can allow for digital or analog user inputs.

Complex controllers can have a plurality of connection modes and statuses. Additionally, the controllers can have various profiles stored thereon for customized button responses. Conventionally, the settings or status of the controller are only visible through communication with another electronic device containing a display.

### BRIEF SUMMARY

In some aspects, the techniques described herein relate to a display device including: a flexible printed circuit assembly (FPCA) including: a display module located at a first end of the FPCA, and an input device located at a second end of the FPCA opposite the first end; and a frame supporting the FPCA, wherein the FPCA is wrapped around the frame where the first end of the FPCA and the second end of the FPCA are adjacent to one another.

In some aspects, the techniques described herein relate to an electronic device controller including: one or more face buttons supported on a face surface; one or more directional input devices on the face surface; and a display device including: a flexible printed circuit assembly (FPCA) including: a display module located at a first end of the FPCA, and an input device located at a second end of the FPCA opposite the first end, and a frame supporting the FPCA, wherein the FPCA is wrapped around the frame where the first end of the FPCA and the second end of the FPCA are adjacent to one another.

In some aspects, the techniques described herein relate to an electronic device controller including: one or more face buttons supported on a face surface; one or more directional input devices on the face surface; and a display device located on a front surface, the display device including: a flexible printed circuit assembly (FPCA) including: a display module located at a first end of the FPCA, and an input device located at a second end of the FPCA opposite the first end, a frame supporting the FPCA, wherein the FPCA is wrapped around the frame where the first end of the FPCA and the second end of the FPCA are adjacent to one another, a body connected to the frame and applying a compressive force to the FPCA between the body and the frame, a display cover positioned between at least a portion of the body and the display module, and a gasket positioned between the display module and the display cover, wherein the gasket is at least 10% compressed by the compressive force.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1-1 is a top view of an electronic device controller, according to at least some embodiments of the present disclosure.

FIG. 1-2 is a side perspective view of the electronic device controller of FIG. 1-1.

FIG. 1-3 is a front view of the electronic device controller of FIG. 1-1.

FIG. 2-1 is a front view of a display device, according to at least some embodiments of the present disclosure.

FIG. 2-2 is a rear perspective view of the display device of FIG. 2-1.

FIG. 3-1 is a front perspective view of a display device with a body removed, according to at least some embodiments of the present disclosure.

FIG. 3-2 is a front perspective view of the display device of FIG. 3-1 with a display cover removed, according to at least some embodiments of the present disclosure.

FIG. 3-3 is a side cross-sectional view of the display device of FIG. 3-1.

FIG. 4-1 is a front perspective view of a display device including a flexible printed circuit assembly (FPCA), according to at least some embodiments of the present disclosure.

FIG. 4-2 is a rear perspective view of the display device of FIG. 4-1.

FIG. 5-1 is top view of an FPCA, according to at least some embodiments of the present disclosure.

FIG. 5-2 is a flat view of the FPCA of FIG. 5-1.

FIG. 6-1 is a front perspective view of a display device with a grounding element, according to at least some embodiments of the present disclosure.

FIG. 6-2 is a rear perspective view of the display device of FIG. 6-1.

FIG. 7 is a front view of a display device with an integrated input button,

FIG. 8 is a front view of a display device with a flexible display cover portion, according to at least some embodiments of the present disclosure.

### DETAILED DESCRIPTION

The present disclosure relates generally to systems and methods for displaying information to a user of an electronic device. More particularly, the present disclosure relates to systems and methods for displaying information to a user of an electronic device controller. In some embodiments, a display device incorporated into the electronic device controller displays information to the user regarding controller information, such as battery status, connection modes, or user profiles. In some embodiments, a display device incorporated into the electronic device controller displays software information of an interactive software application with which the user is interacting via the electronic device controller, such as active items, available content, or avatar information. In some embodiments, a display device incorporated into the electronic device controller displays device information of an electronic device with which the electronic device controller is communicating, such as system time, available software applications, wired or wireless communication status, etc.

In some embodiments, an electronic device controller is space-constrained for the inclusion of a display device. For example, the electronic device controller may be a gamepad, a computer mouse, a joystick, a remote, or other user input device for interacting with an electronic device. Such handheld devices have limited surface area and/or limited volume into which a display device may be incorporated. Additionally, such handheld devices may have a plurality of electronic components and/or antennas that can produce electromagnetic interference in the constrained volume. In some embodiments according to the present disclosure, a display device includes a display module and an input device in a small footprint with little to no interference to allow inclusion in a handheld electronic device controller.

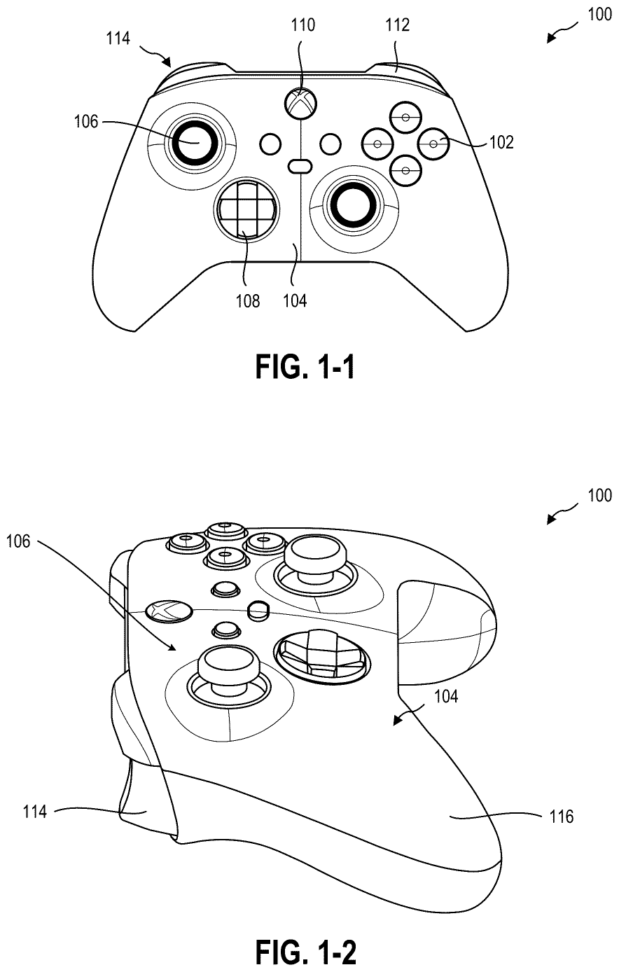

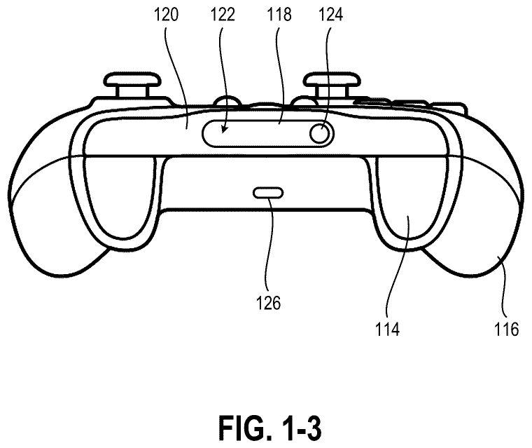

Referring now to FIG. 1-1, in some embodiments, an electronic device controller 100 includes a plurality of input buttons located on or in a body 104 of the electronic device controller 100 with at least one directional input device. It should be understood that while a gamepad is illustrated and described in relation to FIG. 1-1 through FIG. 1-3, electronic device controllers with other form factors are contemplated herein. The directional input devices may include one or more analog thumbsticks 106 and/or one or more directional control pads 108. The input buttons may include face buttons 102, one or more menu or system buttons 110, shoulder buttons 112, trigger buttons 114, rear paddles, etc. In some embodiments, at least one face button 102 is located on a face surface of the body 104 and at least one directional input device is located on the face surface of the body 104.

The thumbsticks 106 and/or directional control pads 108 may be used to control the movement of an avatar or cursor in a two-or three-dimensional virtual environment. The input buttons may be used to provide action commands (e.g., jump, crouch, defend, attack) to an avatar and/or interact with the environment. For example, a face button 102 may be used to provide a jump command to an avatar in an adventure game application, while an analog trigger button 114 may allow a user to precisely modulate a brake input for a racing game application.

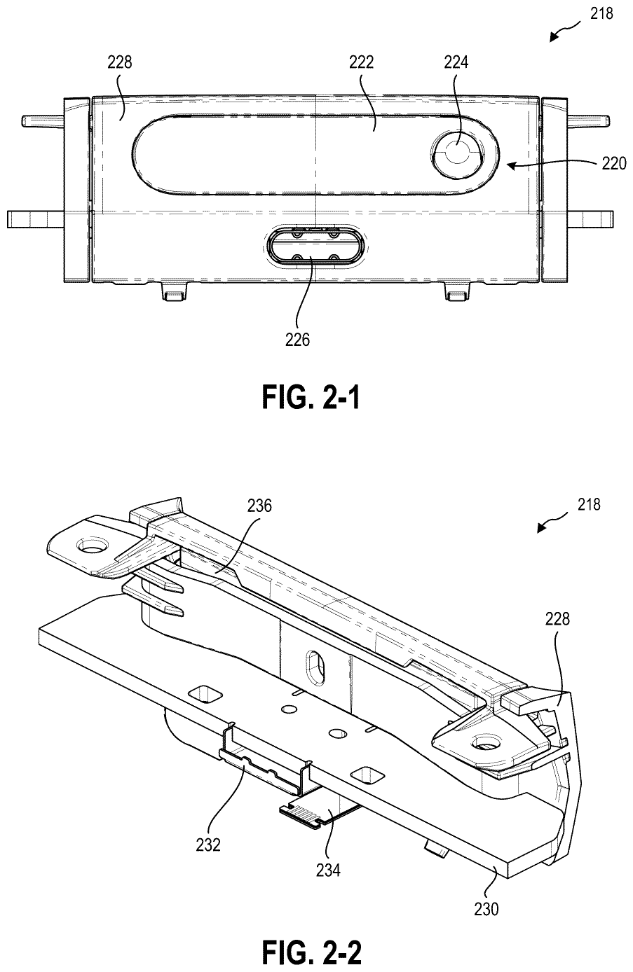

FIG. 1-2 is a side perspective view of the electronic device controller 100 of FIG. 1-1. The electronic device controller 100 may include one or more haptic devices located in the body 104. In some embodiments, the haptic device imparts haptic feedback to the surface of the body 104, such as on a grip 116 of the body 104, through which the user's palm may experience the haptic feedback. In some embodiments, haptic device imparts haptic feedback to a directional input device, such as a thumbstick 106, or to an input button, such as a trigger button 114. In at least one embodiment, a haptic device in or in communication with the trigger button 114 may convey haptic events, such as changes in road surface during braking in the prior example. An electronic device controller 100 may include a plurality of haptic devices in different locations, orientations, and configurations to provide a variety of haptic feedback to the user.

FIG. 1-3 is a front view of the electronic device controller 100 of FIG. 1-1. The electronic device control may include a display device 118 located on the front surface 120 of the electronic device controller 100. The display device 118 includes at least a display cover 122 and an input button 124 integrated into the front surface 120.

In some embodiments, the input button 124 is a connection button that selects a wireless connection mode of the electronic device controller 100. In some embodiments, the electronic device controller 100 includes one or more wireless communication devices (such as a radio frequency antennae and controller), and the connection button may select one of the wireless communication devices and/or select communication mode of the wireless communication device. For example, the connection button may cycle through one or more connections modes, such as Wi-Fi, Bluetooth, Bluetooth Low Energy (BLE), one or more proprietary wireless connection modes, other wireless connection modes, or combinations thereof. In some embodiments, the connection button selects an operation mode for a communication device of the electronic device controller 100, such as a pairable or discoverable mode, a paired or communicating mode, or other communication mode of the communication device.

In some embodiments, the communication device is a wired communication device, such as a USB connection port 126. The USB connection port 126 may, in some examples, provide wired data communication. In some examples, the USB connection port 126 provides electrical communication to charge a battery of the electronic device controller 100 and/or directly power the electronic device controller 100. In some examples, the wired communication device is another type of wired communication device, such as an optical communication device configured to connect to an optical cable.

In some embodiments, the electronic device controller 100 includes a hardware storage device, such as a non-volatile memory storage device that allows the electronic device controller 100 to retain and access one or more connection credentials for different wireless connection modes of the electronic device controller 100. For example, the wireless communication device may connect to a local access point (e.g., wireless router) for a network, and the hardware storage device may have stored thereon login credentials for the local access point. In other examples, the electronic device controller 100 may be configured to communicate with a remote server, such as for interactive software application streaming, and the hardware storage device of the electronic device controller 100 may have stored thereon the login credentials for the interactive software application streaming platform. The display device 118 of the electronic device controller 100 may display to a user such credentials or login status independently of another screen or display.

As described herein, the display device 118 may display connection status (communication mode and/or connected device with which the electronic device controller 100 is in data communication). In other examples, the display device 118 may display other information from a connected electronic device to the user, such as a video game console, a set top box, a television, a laptop computer, a smartphone, or other electronic device in data communication with the electronic device controller 100. For example, the display device 118 may display game status information, latency information, current player assignment (e.g., when connected to a video game console as Player 2), a system time of the connected electronic device, session duration, etc. In other examples, the display device 118 may display controller information to the user regarding the electronic device controller 100, such as battery information including state of charge, remaining battery time, remaining charging time, etc. In yet other examples, the electronic device controller 100 may have stored thereon a plurality of user profiles or controller profiles (such as for different video games or different devices), and the display device 118 may display the status of a selected or active profile.

FIG. 2-1 is a front view of a display device 218 according to at least some embodiments of the present disclosure. As described herein, the front surface of the electronic device controller (such as the electronic device controller 100 of FIG. 1-3) may be space constrained due to the location of other ports, triggers, buttons, directional input devices, haptic engines, audio devices, or other components of the electronic device controller. In some embodiments, the display device 218 is located in and/or supported by a body 228 that includes the USB connection port 226 or other wired connection port. The body 228 may be selectively removable from a body (e.g., body 104) of the electronic device controller to allow repair, replacement, or upgrade of the display device 218.

In some embodiments, a display cover 222 of the display device 218 is flush with the front surface 220 of the body 228. In some embodiments, the display cover 222 presents a dead front when the display is not illuminated. The display cover 222 is otherwise transparent or translucent to allow light from the display module to emanate from the display device 218. For example, the display cover 222 may provide an appearance of a substantially continuous surface and/or material of the body 228 when not illuminated. In some embodiments, the display cover 222 has a matte finish. In some embodiments, the display cover 222 has a satin finish. In some embodiments, the display cover 222 has a reflective finish (e.g., a substantially specular reflection). In some embodiments, the display cover 222 has a finish with a similar reflectivity to the body 228.

The display cover 222 may surround the input button 224, as illustrated in FIG. 2-1 within the plane of the display cover 222. For example, the input button 224 may be located within and movable within an aperture of the display cover 222. In other words, at least a portion of the display cover 222 is substantially continuous around the input button 224 within the plane of the display cover 222. In some embodiments, the input button 224 is adjacent to the display cover 222 and at least a portion of the input button 224 is not surrounded by the display cover 222 in the plane of the display cover 222.

FIG. 2-2 is a rear perspective view of the embodiment of a display device of FIG. 2-1. In some embodiments, the display device 218 connects to a printed circuit board assembly (PCBA) 230 of the electronic device controller. For example, the PCBA 230 may further support the USB connection port 226 or other wired connection port. The display device 218 includes a flexible connector 234 that connects to one or more components of the PCBA 230 to provide electrical and/or data communication between components of the display device 218 and other components (such as a power source or communication device) of the electronic device controller.

The body 228 of the display device 218, in some embodiments, connects to a frame 236 of the display device 218 to retain components, such as the display cover and display module (as described herein), therebetween. In some embodiments, the body 228 and frame 236 connect to one another by other connection methods other than a snap fit. In some examples, the body 228 and frame 236 connect to one another by an adhesive. In some examples, the body 228 and frame 236 connect to one another by a mechanical fastener, such as a clip, clamp, threaded fastener, rivet, or other discrete mechanical fastener. In some examples, the body 228 and frame 236 connect to one another by a friction fit.

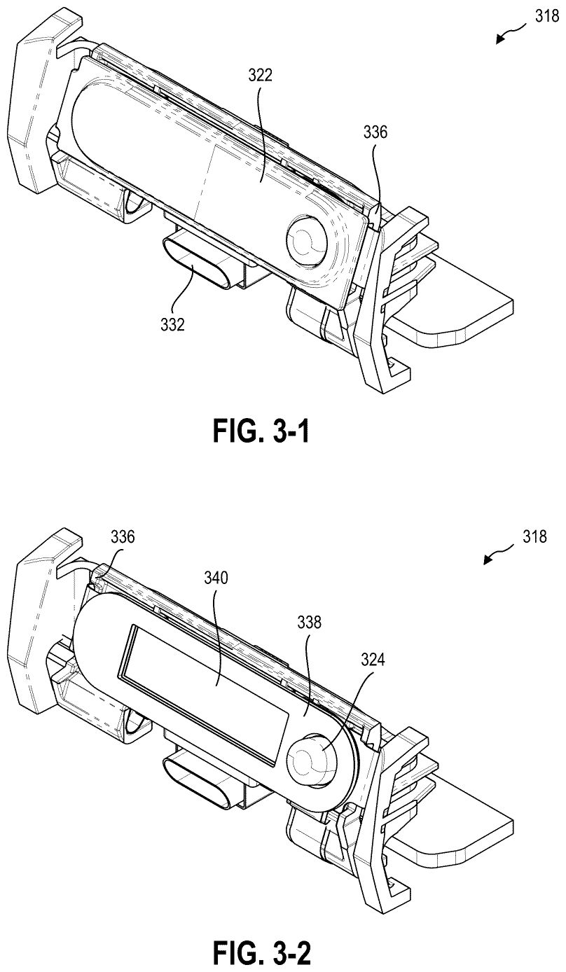

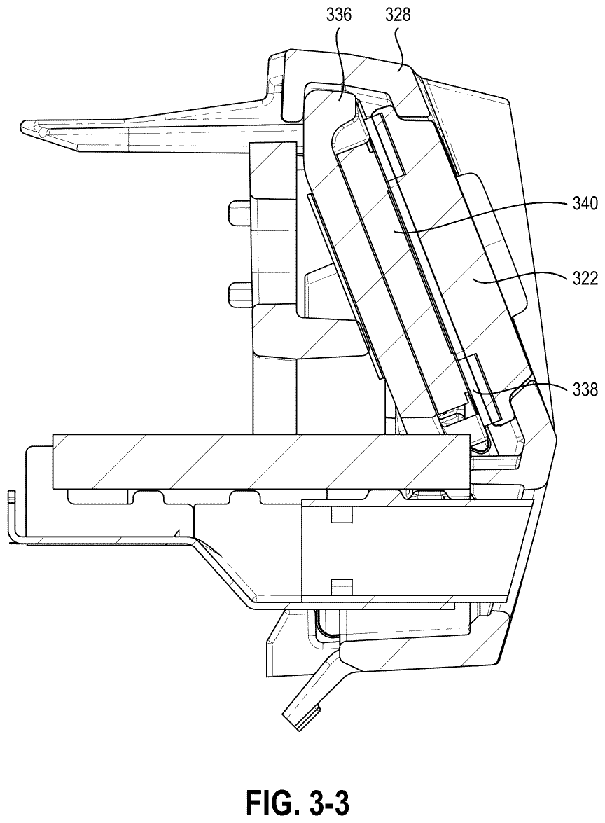

FIG. 3-1 is a front perspective view of the embodiment of a display device 318 (such as described in relation to FIG. 2-1) with a body of the display device 318 removed. The display cover 322, in some embodiments, has a flange or other extension of the display cover 322 that is contacted by the body (not shown) to compress the display cover 322 against a frame 336. The body and frame 336, therefore, may limit and/or prevent the movement of the display cover 322, retaining the display cover 322 in the display device 318. For example, the frame 336 may support the display cover 322 with a gap or other clearance between the display cover 322 and the display module. The gap or other clearance may provide protection to the display module in the event of a force applied to the display cover 322, and the display cover 322 may thereby transfer the force to the frame 336 instead of the display module. In some embodiments, the display device 318 includes a wired connection connector 332 in contact with the frame 336. In other embodiments, the frame 336 is separate from and not integrated with the wired connection connector 332.

FIG. 3-2 is a front perspective view of the embodiment of a display device of FIG. 3-1 with the display cover 322 removed and the gasket 338 behind the display cover 322 visible. The display module 340 is visible through an aperture in the gasket 338. The gasket 338 is or includes a compressible material. In some embodiments, the gasket 338 is positioned around the input button 324 similarly to the display cover. The input button 324 is located through an aperture in the gasket 338.

In some embodiments, the gasket 338 limits and/or prevents light leakage from the display module 340. In some embodiments, the gasket 338 overlaps at least a portion of a flange, shoulder, or other lateral extension of the input button 324 proximate to the frame 336. The compression of the gasket 338 between the display cover 322 and the frame 336 holds the display module 340 and/or input button 324 in place. Further, the gasket 338 may press the input button 324 against an input device under the input button 324 so there is no pre-travel when a user presses the input button.

FIG. 3-3 is a perspective cross-sectional view of the embodiment of a display device of FIG. 3-1. The gasket 338, in some embodiments, is under at least some compression between a bezel of the display module 340 and the display cover 322. For example, the gasket 338 may be under at least 10% compression when the frame 336 and body 328 are snapped together, such as the body 328 being snapped around the back of the frame 336 (or the frame 336 and body 328 otherwise being connected to one another). In another example, the gasket 338 is under at least 25% compression when the frame 336 and body 328 are connected. In another example, the gasket 338 is under at least 50% compression when the frame 336 and body 328 are connected. In some embodiments, the display module 340 is compressed against the frame 336. In some embodiments, a second gasket or other compressible material is positioned between the frame 336 and the display module 340 to limit and/or prevent force being inadvertently concentrated against the display module from uneven surfaces created during manufacturing (such as due to machining or injection molding tolerances).

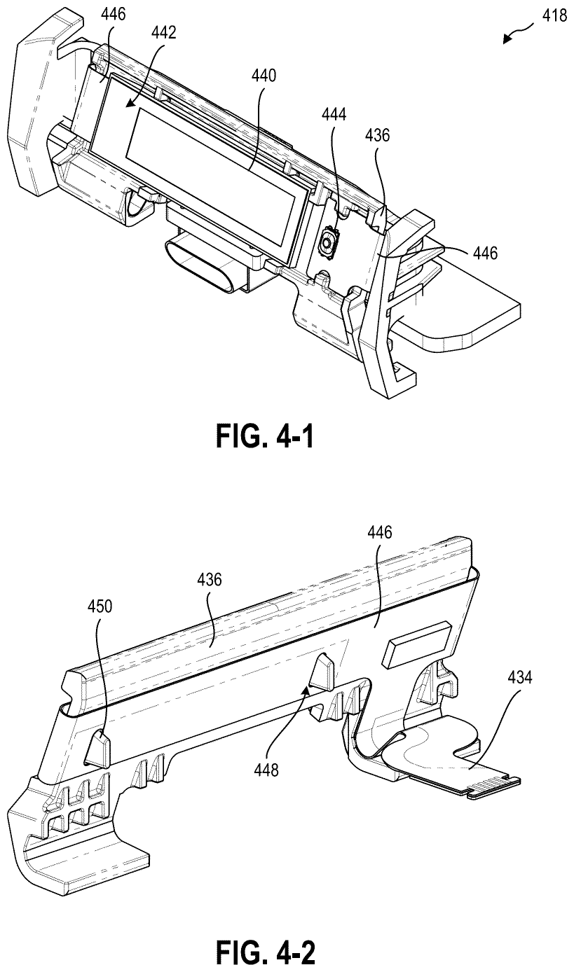

FIG. 4-1 is a front perspective view of the embodiment of a display device 418, such as the display device 318 of FIG. 3-1, with the display cover, gasket, and input button further removed. In some embodiments, the display module 440 is integrated with a display controller 442. In some embodiments, the display module 440 is in data communication with a display controller 442 also supported by the frame 436 of the display device 418.

The display device 418 further includes an input device 444 or other contact sensor configured to measure force applied to the input button and transmitted thereto. In some embodiments, the input device 444 is a pressure sensor, a touch sensor (e.g., capacitive touch sensor), a contact switch, a force sensor, or any other device by which a user's press may be detected and registered. The input device 444 is, therefore, configured to detect a user pressing the input button and/or on the display cover to provide user inputs to the display device 418 and/or the electronic device controller, as a whole. In some embodiments, both the display module 440 and the input device 444 are positioned on a flexible printed circuit assembly (FPCA) 446. In some embodiments, the display module 440 (and optionally the display controller 442) is located at a first end of the FPCA 446 and the input device 444 is located at a second opposite end of the FPCA 446. In some embodiments, the FPCA 446 is wrapped around the frame 436 with the display module 440 and the input device 444 substantially adjacent to one another. The display module 440 and the input device 444 being located at opposite ends of the FPCA 446, in some embodiments, limits electrical interference therebetween. The display module 440 and the input device 444 being located at opposite ends of the FPCA 446, in some embodiments, allows the display module 440 to be located in a center of the display device. For example, the display module 440 and the input device 444 being located at opposite ends of the FPCA 446, in some embodiments, allows the display module 440 to be located closer to one another than directing traces around other adjacent elements. In some embodiments, the display module 440 and the input device 444 being located at opposite ends of the FPCA 446 limits and/or prevents force applied to the input device 444 (and the second end of the FPCA 446) being transmitted to the display module 440 (and to the first end of the FPCA 446), limiting wear and fatigue on the display module 440 and FPCA 446.

FIG. 4-2 is a rear perspective view of the embodiment of the display device 418 of FIG. 4-1. The FPCA 446 wraps around the frame 436. In some embodiments, the FPCA 446 includes a plurality of alignment features 448. The alignment features 448 in the FPCA 446 are configured to mate with complementary alignment features 450 in the frame 436. In some embodiments, the alignment features 448 in the FPCA 446 are apertures or notches, and the complementary alignment features 450 are posts or other protrusions from the frame 436 configured to mate with the alignment features 448 in the FPCA 446. In some embodiments, the alignment features 448 in the FPCA 446 are posts or protrusions from the FPCA 446, and the complementary alignment features 450 are notches or apertures in the frame 436 configured to mate with the alignment features 448 in the FPCA 446.

In some embodiments, the FPCA 446 has a T-junction for flexible connector portion with connector 434 that connects to the PCBA (such as the PCBA described in relation to FIG. 2-2). In some embodiments, the FPCA 446 is affixed to the frame 436 by an adhesive or other retention mechanism after alignment by the alignment features. Such alignment features can ensure the connector 434 aligns with the PCBA, the display module 440 and/or the input device 444 align with the display cover, and other elements align with components of the electronic device controller.

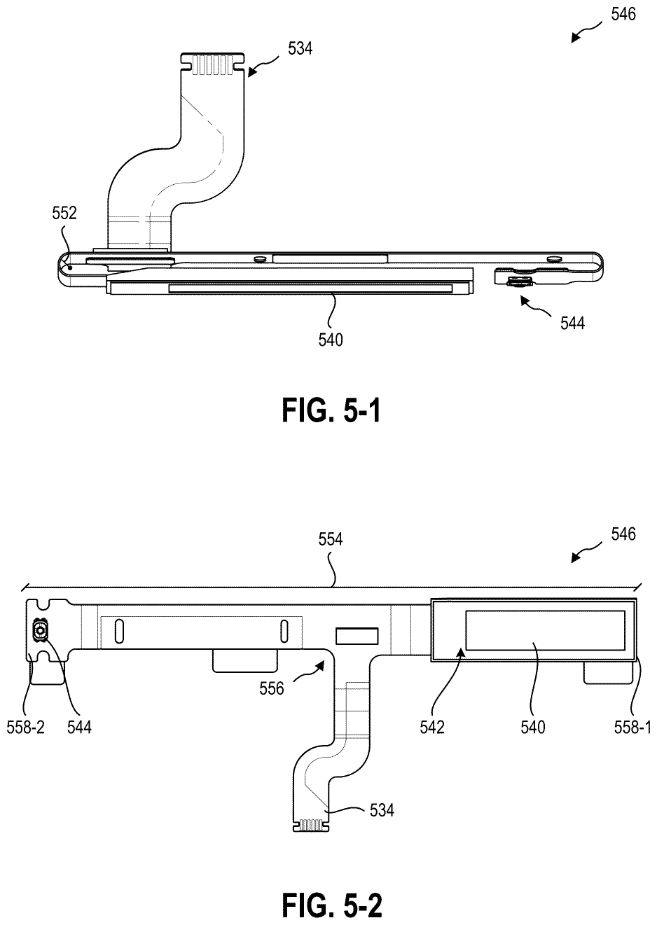

FIG. 5-1 is a top view of the embodiment of an FPCA 546, such as that described in relation to FIG. 4-1. In some embodiments, the FPCA 546 has a minimum radius of curvature 552 of 1 millimeter (mm) when wrapping around a frame. In some embodiments, the FPCA 546 has a minimum radius of curvature 552 of 0.5 mm when wrapping around a frame. As described herein, the display module 540 and the input device 544 are positioned substantially adjacent to one another in the assembled configuration with the FPCA 546 wrapped around a frame. In some embodiments, a gap between the ends of the FPCA 546 is less than 5 mm. In some embodiments, a gap between the ends of the FPCA 546 is less than 2.5 mm. In some embodiments, a gap between the ends of the FPCA 546 is less than 1 mm.

FIG. 5-2 is a flat view of the FPCA 546 of FIG. 5-1 laid in a single plane. For example, the FPCA 546 may be laid flat prior to wrapping around the frame. In some embodiments, the FPCA 546 has a length 554 between a first end 558-1 and a second end 558-2. In some embodiments, the display module 540 (and display controller 542) are integrated into the first end 558-1. In some embodiments, the input device 544 is integrated into the second end 558-2.

The FPCA 546 has a T-junction 556, in some embodiments, located between the input device 544 and display module 540. For example, the electrical traces along the FPCA 546 may have a maximum allowable length before an electrical signal along the traces degrades (i.e., a signal-to-noise ratio decreases below a target value), and a signal repeater or processor is required. As described herein, embodiments of display devices according to the present disclosure may be used in space-constrained applications. Placement of the T-junction 556 proximate a center of the length 554 of the FPCA 546 can balance a trace length of electrical traces in the FPCA 546 and to the connector 534 between the two ends of the FPCA 546. Therefore, the need for additional signal handling components can be limited or eliminated.

In some embodiments, the FPCA 546 has a length 554 with the T-junction 556 positioned at a location along the length 554 that is substantially equidistant from the two ends (i.e., the first end 558-1 and the second end 558-2).

In some embodiments, the T-junction 556 is within a center 50% of the length 554 of the FPCA 546. For example, the T-junction 556 may be located between 25% and 75% of the length 554 of the FPCA 546 from the first end 558-1 toward the second end 558-2. In some embodiments, the T-junction 556 is within a center 33% of the length 554 of the FPCA 546. In some embodiments, the T-junction 556 is within a center 20% of the length 554 of the FPCA 546. In some embodiments, the T-junction 556 is located within a center region of the length 554 of the FPCA 546 according to the descriptions herein, and the T-junction 556 is closer to the first end 558-1 with the display module 540 than the second end 558-2 with the input device 544. For example, a shorter electrical trace length (and associated improved signal quality) may be prioritized for the display module 540 relative to the input device 544. In some embodiments, the electrical trace length is no more than 50 mm.

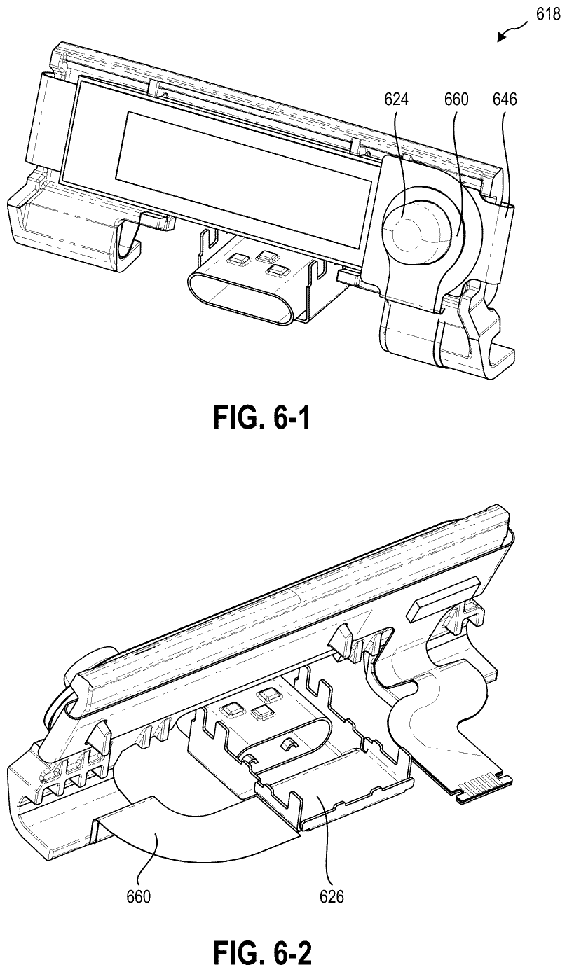

In some examples, electrical shock or other electrical ingress is possible while a user presses the input button. The electrical shock can damage the FPCA or other components of the display device. In some embodiments, a grounding element can electrically insulate the components of the display device from electrical ingress. FIG. 6-1 is a front perspective view of an embodiment of a display device 618 with a grounding element 660. In some embodiments, part of the grounding element 660 is positioned contacting the input button 624. For example, part of the grounding element 660 may be positioned circumferentially around the input button 624. In some embodiments, the grounding element 660 may be positioned between the input button 624 and the input device 644 and/or between the input button 624 and the FPCA 646.

In some embodiments, the grounding element 660 is electrically conductive to provide an electrical path to ground to an electrical sink that is less likely to be damaged by an electrical shock than the FPCA 646, display module, and/or input device.. In some examples, the grounding element 660 may include or be made of a graphite fabric or other flexible conductive material. The grounding element 660 may wrap around to a rear of the display device 618 to connect to the PCBA or other component and provide a path to ground.

FIG. 6-2 is a rear perspective view of the embodiment of a display device of FIG. 6-1. In some embodiments, the grounding element 660 contacts or is connected to the USB connection port 626 or bracket thereof. For example, the grounding element 660 may ground to earth when connected to a USB cable that is connected to earth ground. In some examples, the USB connection port 626 and/or bracket may have a larger conductive mass than the FPCA to act as an electrical sink and disperse the electrical charge, even when not connected to an earth ground by a cable. In some embodiments, the display module itself is grounded through the connector. For example, a ground trace may be located around the display module to provide a ground path to the connector. Additionally, the gasket may be electrically conductive to provide a ground path.

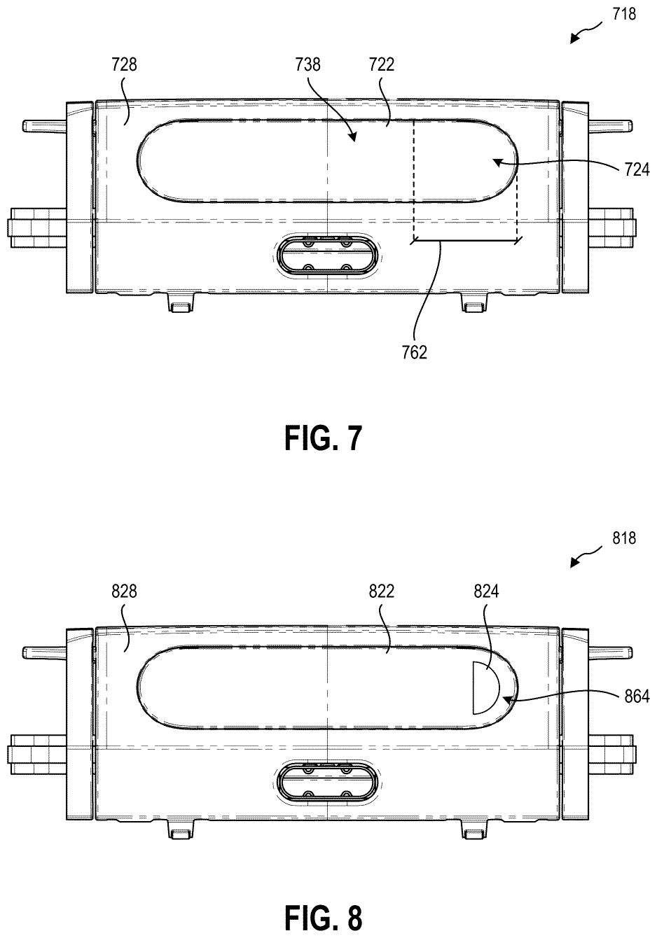

In some embodiments, a display device lacks a discrete input button. In some examples, lacking a discrete input button may limit and/or prevent electrical shock ingress. In some examples, lacking a discrete input button may limit and/or prevent light leakage. In some examples, lacking a discrete input button may provide a more uniform visual presentation of the display device. FIG. 7 is a front view of an embodiment of a display device 718 without a discrete input button.

In some embodiments, the display cover 722 is substantially continuous across the surface thereof. In such an embodiment, the display cover 722 may flex or tilt relative to the body 728 of the display device 718 to depress an input device or other contact located underneath the display cover 722. For example, a gasket 738 may be located behind only a portion of the display cover 722, and an unsupported region 762 may flex or otherwise move inward to depress the sensor. The unsupported region 762 may, therefore, function as an integrated input button 724. In other examples, a portion of the display cover 722 covering the sensor is lesser-supported by a thinner or lower durometer gasket that allows such lesser-supported portion of the display cover 722 to flex or move relative to the body 728 and depress the sensor as an integrated input button 724.

In some embodiments, the unsupported region 762 (or lesser-supported region) is 25% of the display cover 722. In some embodiments, the unsupported region 762 (or lesser-supported region) is 33% of the display cover 722. In some embodiments, the unsupported region 762 (or lesser-supported region) is 50% of the display cover 722.

FIG. 8 is a front view of an embodiment of a display device 818 with a flexible portion 864 of the display cover 822. As described herein, some embodiments of a display cover (such as that described in relation to FIG. 2-1) have an aperture therethrough in which a discrete input button is located. In some embodiments, the display cover 822 has an integrated input button 824 formed by a flexible portion 864 of the display cover 822 that is movable relative to the surrounding display cover 822. For example, a cut or other separation in the display cover 822 allows a flexible portion to bend relative to the surrounding display cover 822. In some embodiments, the flexible portion 864 has a different thickness than other portions of the display cover 822. For example, a flexible portion 864 that is thinner or has thinner portions than the surrounding display cover 822 may preferentially flex when a user applies a force to the integrated input button 824 of the display cover 822.

By integrating the display device into the front surface or face surface of an electronic device controller, the display device does not distract the user from engagement with the controller, while providing detailed and relevant information to the user when needed.

### INDUSTRIAL APPLICABILITY

The present disclosure relates generally to systems and methods for displaying information to a user of an electronic device. More particularly, the present disclosure relates to systems and methods for displaying information to a user of an electronic device controller. In some embodiments, a display device incorporated into the electronic device controller displays information to the user regarding controller information, such as battery status, connection modes, or user profiles. In some embodiments, a display device incorporated into the electronic device controller displays software information of an interactive software application with which the user is interacting via the electronic device controller, such as active items, available content, or avatar information. In some embodiments, a display device incorporated into the electronic device controller displays device information of an electronic device with which the electronic device controller is communicating, such as system time, available software applications, wired or wireless communication status, etc.

In some embodiments, an electronic device controller is space-constrained for the inclusion of a display device. For example, the electronic device controller may be a gamepad, a computer mouse, a joystick, a remote, or other user input device for interacting with an electronic device. Such handheld devices have limited surface area and/or limited volume into which a display device may be incorporated. Additionally, such handheld devices may have a plurality of electronic components and/or antennas that can produce electromagnetic interference in the constrained volume. In some embodiments according to the present disclosure, a display device includes a display module and an input device in a small footprint with little to no interference to allow inclusion in a handheld electronic device controller.

In some embodiments, an electronic device controller includes a plurality of input buttons located on or in a body of the electronic device controller with at least one directional input device. The directional input devices may include one or more analog thumbsticks and/or one or more directional control pads. The input buttons may include face buttons, one or more menu or system buttons, shoulder buttons, trigger buttons, rear paddles, etc. In some embodiments, at least one face button is located on a face surface of the body and at least one directional input device is located on the face surface of the body.

The thumbsticks and/or directional control pads may be used to control the movement of an avatar or cursor in a two-or three-dimensional virtual environment. The input buttons may be used to provide action commands (e.g., jump, crouch, defend, attack) to an avatar and/or interact with the environment. For example, a face button may be used to provide a jump command to an avatar in an adventure game application, while an analog trigger button may allow a user to precisely modulate a brake input for a racing game application.

The electronic device controller may include one or more haptic devices located in the body. In some embodiments, the haptic device imparts haptic feedback to the surface of the body, such as on a grip of the body, through which the user's palm may experience the haptic feedback. In some embodiments, haptic device imparts haptic feedback to a directional input device, such as a thumbstick, or to an input button, such as a trigger button. In at least one embodiment, a haptic device in or in communication with the trigger button may convey haptic events, such as changes in road surface during braking in the prior example. An electronic device controller may include a plurality of haptic devices in different locations, orientations, and configurations to provide a variety of haptic feedback to the user.

The electronic device control may include a display device located on the front surface of the electronic device controller. The display device includes at least a display cover and an input button integrated into the front surface. In some embodiments, the input button is a connection button that selects a wireless connection mode of the electronic device controller. In some embodiments, the electronic device controller includes one or more wireless communication devices (such as a radio frequency antennae and controller), and the connection button may select one of the wireless communication devices and/or select communication mode of the wireless communication device. For example, the connection button may cycle through one or more connections modes, such as Wi-Fi, Bluetooth, Bluetooth Low Energy (BLE), one or more proprietary wireless connection modes, other wireless connection modes, or combinations thereof. In some embodiments, the connection button selects an operation mode for a communication device of the electronic device controller 100, such as a pairable or discoverable mode, a paired or communicating mode, or other communication mode of the communication device.

In some embodiments, the communication device is a wired communication device, such as a USB connection port. The USB connection port may, in some examples, provide wired data communication. In some examples, the USB connection port provides electrical communication to charge a battery of the electronic device controller and/or directly power the electronic device controller. In some examples, the wired communication device is another type of wired communication device, such as an optical communication device configured to connect to an optical cable.

In some embodiments, the electronic device controller includes a hardware storage device, such as a non-volatile memory storage device that allows the electronic device controller to retain and access one or more connection credentials for different wireless connection modes of the electronic device controller. For example, the wireless communication device may connect to a local access point (e.g., wireless router) for a network, and the hardware storage device may store thereon login credentials for the local access point. In other examples, the electronic device controller may be configured to communicate with a remote server, such as for interactive software application streaming, and the hardware storage device of the electronic device controller may store thereon the login credentials for the interactive software application streaming platform. The display device of the electronic device controller may display to a user such credentials or login status independently of another screen or display.

As described herein, the display device may display connection status (communication mode and/or connected device with which the electronic device controller is in data communication). In other examples, the display device may display other information from a connected electronic device to the user, such as a video game console, a set top box, a television, a laptop computer, a smartphone, or other electronic device in data communication with the electronic device controller. For example, the display device may display game status information, latency information, current player assignment (e.g., when connected to a video game console as Player 2), a system time of the connected electronic device, session duration, etc. In other examples, the display device may display controller information to the user regarding the electronic device controller, such as battery information including state of charge, remaining battery time, remaining charging time, etc. In yet other examples, the electronic device controller may have stored thereon a plurality of user profiles or controller profiles (such as for different video games or different devices), and the display device may display the status of a selected or active profile.

As described herein, the front surface of the electronic device controller may be space constrained due to the location of other ports, triggers, buttons, directional input devices, haptic engines, audio devices, or other components of the electronic device controller. In some embodiments, the display device is located in and/or supported by a body that includes the USB connection port or other wired connection port. The body of the display device may be selectively removable from a body of the electronic device controller to allow repair, replacement, or upgrade of the display device.

In some embodiments, a display cover of the display device is flush with the front surface of the body. In some embodiments, the display cover presents a dead front when the display module is not illuminated. The display cover is otherwise transparent or translucent to allow light from the display module to emanate from the display device. For example, the display cover may provide an appearance of a substantially continuous surface and/or material of the body when not illuminated. In some embodiments, the display cover has a matte finish. In some embodiments, the display cover has a satin finish. In some embodiments, the display cover has a reflective finish (e.g., a substantially specular reflection). In some embodiments, the display cover has a finish with a similar reflectivity to the body.

The display cover may surround the input button within the plane of the display cover. For example, the input button may be located within and movable within an aperture of the display cover. In other words, at least a portion of the display cover is substantially continuous around the input button within the plane of the display cover. In some embodiments, the input button is adjacent to the display cover and at least a portion of the input button is not surrounded by the display cover in the plane of the display cover.

In some embodiments, the display device connects to a printed circuit board assembly (PCBA) of the electronic device controller. For example, the PCBA may further support the USB connection port or other wired connection port. The display device includes a flexible connector that connects to one or more components of the PCBA to provide electrical and/or data communication between components of the display device and other components (such as a power source or communication device) of the electronic device controller.

The body of the display device, in some embodiments, connects to a frame of the display device to retain components, such as the display cover and display module (as described herein), therebetween. In some embodiments, the body and frame connect to one another by other connection methods other than a snap fit. In some examples, the body and frame connect to one another by an adhesive. In some examples, the body and frame connect to one another by a mechanical fastener, such as a clip, clamp, threaded fastener, rivet, or other discrete mechanical fastener. In some examples, the body and frame connect to one another by a friction fit.

The display cover, in some embodiments, has a flange or other extension of the display cover that is contacted by the body (not shown) to compress the display cover against a frame. The body and frame, therefore, may limit and/or prevent the movement of the display cover, retaining the display cover in the display device. In some embodiments, the display device includes a wired connection connector in contact with the frame. In other embodiments, the frame is separate from and not integrated with the wired connection connector.

In some embodiments, the display device includes a gasket. The display module is visible through an aperture in the gasket. The gasket is or includes a compressible material. In some embodiments, the gasket is positioned around the input button similarly to the display cover. The input button is located through an aperture in the gasket.

In some embodiments, the gasket limits and/or prevents light leakage from the display module. In some embodiments, the gasket limits and/or prevents light leakage to the display module. In some embodiments, the gasket overlaps at least a portion of a flange, shoulder, or other lateral extension of the input button proximate to the frame. The compression of the gasket between the display cover and the frame holds the display module and/or input button in place.

The gasket, in some embodiments, is under at least some compression between a bezel of the display module and the display cover. For example, the gasket may be under at least 10% compression when the frame and body are snapped together, such as the body being snapped around the back of the frame (or the frame and body otherwise being connected to one another). In another example, the gasket is under at least 25% compression when the frame and body are connected. In another example, the gasket is under at least 50% compression when the frame and body are connected. In some embodiments, the display module is compressed against the frame. In some embodiments, a second gasket or other compressible material is positioned between the frame and the display module to limit and/or prevent force being inadvertently concentrated against the display module from uneven surfaces created during manufacturing (such as due to machining or injection molding tolerances).

In some embodiments, the display module is integrated with a display controller. In some embodiments, the display module is in data communication with a display controller also supported by the frame of the display device.

The display device further includes an input device or other contact sensor configured to measure force applied to the input button and/or transmitted to the input device. In some embodiments, the input device is a pressure sensor, a touch sensor (e.g., capacitive touch sensor), a contact switch, a force sensor, or any other device by which a user's press may be detected and registered. The input device is, therefore, configured to detect a user pressing the input button and/or display cover to provide user inputs to the display device and/or the electronic device controller, as a whole. In some embodiments, both the display module and the input device are positioned on a flexible printed circuit assembly (FPCA). In some embodiments, the display module (and optionally the display controller) is located at a first end of the FPCA, and the input device is located at a second opposite end of the FPCA. In some embodiments, the FPCA is wrapped around the frame with the display module and the input device substantially adjacent to one another. The display module and the input device being located at opposite ends of the FPCA, in some embodiments, limits electrical interference therebetween. In some embodiments, the display module and the input device being located at opposite ends of the FPCA limits and/or prevents force applied to the input device (and the second end of the FPCA) being transmitted to the display module (and to the first end of the FPCA), limiting wear and fatigue on the display module and FPCA.

The FPCA wraps around the frame. In some embodiments, the FPCA includes a plurality of alignment features. The alignment features in the FPCA are configured to mate with complementary alignment features in the frame. In some embodiments, the alignment features in the FPCA are apertures or notches, and the complementary alignment features are posts or other protrusions from the frame configured to mate with the alignment features in the FPCA. In some embodiments, the alignment features in the FPCA are posts or protrusions from the FPCA, and the complementary alignment features are notches or apertures in the frame configured to mate with the alignment features in the FPCA.

In some embodiments, the FPCA has a T-junction for flexible connector portion with connector that connects to the PCBA. In some embodiments, the FPCA is affixed to the frame by an adhesive or other retention mechanism after alignment by the alignment features. Such alignment features can ensure the connector aligns with the PCBA, the display module and/or the input device align with the display cover, and other elements align with components of the electronic device controller.

In some embodiments, the FPCA has a minimum radius of curvature of 1 millimeter (mm) when wrapping around a frame. In some embodiments, the FPCA has a minimum radius of curvature of 0.5 mm when wrapping around a frame. As described herein, the display module and the input device are positioned substantially adjacent to one another in the assembled configuration with the FPCA wrapped around a frame. In some embodiments, a gap between the ends of the FPCA is less than 5 mm. In some embodiments, a gap between the ends of the FPCA is less than 2.5 mm. In some embodiments, a gap between the ends of the FPCA is less than 1 mm.

For example, the FPCA may be laid flat prior to wrapping around the frame. In some embodiments, the FPCA has a length between a first end and a second end. In some embodiments, the display module (and display controller) is integrated into the first end. In some embodiments, the input device is integrated into the second end.

The FPCA has a T-junction, in some embodiments, located between the input device and display module. For example, the electrical traces along the FPCA may have a maximum allowable length before an electrical signal along the traces degrades (i.e., a signal-to-noise ratio decreases below a target value), and a signal repeater or processor is required. As described herein, embodiments of display devices according to the present disclosure may be used in space-constrained applications. Placement of the T-junction proximate a center of the length of the FPCA can balance a trace length of electrical traces in the FPCA and to the connector between the two ends of the FPCA. Therefore, the need for additional signal handling components can be limited or eliminated.

In some embodiments, the FPCA has a length with the T-junction positioned at a location along the length that is substantially equidistant from the two ends (i.e., the first end and the second end).

In some embodiments, the T-junction is within a center 50% of the length of the FPCA. For example, the T-junction may be located between 25% and 75% of the length of the FPCA from the first end toward the second end. In some embodiments, the T-junction is within a center 33% of the length of the FPCA. In some embodiments, the T-junction is within a center 20% of the length of the FPCA. In some embodiments, the T-junction is located within a center region of the length of the FPCA according to the descriptions herein, and the T-junction is closer to the first end with the display module than the second end with the input device. For example, a shorter electrical trace length (and associated improved signal quality) may be prioritized for the display module relative to the input device. In some embodiments, the electrical trace length is no more than 50 mm.

In some examples, electrical shock or other electrical ingress is possible while a user presses the input button. The electrical shock can damage the FPCA or other components of the display device. In some embodiments, a grounding element can electrically insulate the components of the display device from electrical ingress. In some embodiments, part of the grounding element is positioned contacting the input button. For example, part of the grounding element may be positioned circumferentially around the input button. In some embodiments, the grounding element may be positioned between the input button and the input device and/or between the input button and the FPCA.

In some embodiments, the grounding element is electrically conductive to provide an electrical path to ground to an electrical sink that is less likely to be damaged by an electrical shock than the FPCA and/or input device. In some examples, the grounding element may include or be made of a graphite fabric or other flexible conductive material. The grounding element may wrap around to a rear of the display device to connect to the PCBA or other component and provide a path to ground.

In some embodiments, the grounding element contacts or is connected to the USB connection port or bracket thereof. For example, the grounding element may ground to earth when connected to a USB cable that is connected to earth ground. In some examples, the USB connection port and/or bracket may have a larger conductive mass than the FPCA to act as an electrical sink and disperse the electrical charge, even when not connected to an earth ground by a cable. In some embodiments, the display module itself is grounded through the connector. Additionally, the gasket may be electrically conductive to provide a ground path.

In some embodiments, a display device lacks a discrete input button. In some examples, lacking a discrete input button may limit and/or prevent electrical shock ingress. In some examples, lacking a discrete input button may limit and/or prevent light leakage. In some examples, lacking a discrete input button may provide a more uniform visual presentation to the display device.

In some embodiments, the display cover is substantially continuous across the surface thereof. In such an embodiment, the display cover may flex or tilt relative to the body of the display device to depress an input device or other contact located underneath the display cover. For example, a gasket may be located behind only a portion of the display cover, and an unsupported region may flex or otherwise move inward to depress the sensor. The unsupported region may, therefore, function as an integrated input button. In other examples, a portion of the display cover covering the sensor is lesser-supported by a thinner or lower durometer gasket that allows such lesser-supported portion of the display cover to flex or move relative to the body and depress the sensor as an integrated input button.

In some embodiments, the unsupported region (or lesser-supported region) is 25% of the display cover. In some embodiments, the unsupported region (or lesser-supported region) is 33% of the display cover. In some embodiments, the unsupported region (or lesser-supported region) is 50% of the display cover.

As described herein, some embodiments of a display cover have an aperture therethrough in which a discrete input button is located. In some embodiments, the display cover has an integrated input button formed by a flexible portion of the display cover that is movable relative to the surrounding display cover. For example, a cut or other separation in the display cover allows a flexible portion to bend relative to the surrounding display cover. In some embodiments, the flexible portion has a different thickness than other portions of the display cover. For example, a flexible portion that is thinner or has thinner portions than the surrounding display cover may preferentially flex when a user applies a force to the integrated input button of the display cover.

By integrating the display device into the front surface or face surface of an electronic device controller, the display device does not distract the user from engagement with the controller, while providing detailed and relevant information to the user when needed.

The present disclosure relates to systems and methods for providing visual information to a user of an electronic device controller according to at least the examples provided in the clauses below:

Clause 1. A display device comprising: a flexible printed circuit assembly (FPCA) including: a display module located at a first end of the FPCA, and an input device located at a second end of the FPCA opposite the first end; and a frame supporting the FPCA, wherein the FPCA is wrapped around the frame where the first end of the FPCA and the second end of the FPCA are adjacent to one another.

Clause 2. The display device of clause 1, further comprising a display controller integrated into the display module.

Clause 3. The display device of clause 1 or 2, further comprising a flexible connector configured to provide electrical communication to the display module and the input device, wherein the flexible connector is connected to the FPCA at a T-junction between the first end and the second end.

Clause 4. The display device of clause 3, wherein the T-junction is located in a center 50% of a length of the FPCA between the first end and the second end.

Clause 5. The display device of clause 4, wherein the T-junction is located equidistant from the first end and the second end.

Clause 6. The display device of clause 4, wherein the T-junction is located closer to the first end than the second end.

Clause 7. The display device of clause 3, wherein the FPCA includes no signal handling components in an electrical trace between the display module and the flexible connector.

Clause 8. The display device of any preceding clause, further comprising a display cover that covers both the display module and the input device.

Clause 9. The display device of clause 8, wherein the display cover presents a dead front when the display module is not illuminated.

Clause 10. The display device of clause 8, further comprising an input button that is movable relative to a body of the display device and configured to transmit a force to the input device.

Clause 11. The display device of clause 10, wherein the input button is a discrete input button that is movable relative to the display cover.

Clause 12. The display device of clause 10, wherein the input button is an integrated input button integrated into the display cover.

Clause 13. The display device of clause 8, further comprising a grounding element positioned between the display cover and at least a portion of the FPCA.

Clause 14. The display device of clause 13, wherein the grounding element is electrically connected to a wired connection port.

Clause 15. An electronic device controller comprising: one or more face buttons supported on a face surface; one or more directional input devices on the face surface; and a display device including: a flexible printed circuit assembly (FPCA) including: a display module located at a first end of the FPCA, and an input device located at a second end of the FPCA opposite the first end, and a frame supporting the FPCA, wherein the FPCA is wrapped around the frame where the first end of the FPCA and the second end of the FPCA are adjacent to one another.

Clause 16. The electronic device controller of clause 15, wherein the display device is located on a front surface of the electronic device controller.

Clause 17. The electronic device controller of clause 15 or 16, wherein the display device is configured to display controller information.

Clause 18. The electronic device controller of any of clauses 15 through 17, further comprising a wireless communication device and wherein the display device is configured to display a wireless connection mode.

Clause 19. The electronic device controller of any of clauses 15 through 18, further comprising a wired connection port, and wherein the display device further including a grounding element electrically connected to the wired connection port.

Clause 20. An electronic device controller comprising: one or more face buttons supported on a face surface; one or more directional input devices on the face surface; and a display device located on a front surface, the display device including: a flexible printed circuit assembly (FPCA) including: a display module located at a first end of the FPCA, and an input device located at a second end of the FPCA opposite the first end, a frame supporting the FPCA, wherein the FPCA is wrapped around the frame where the first end of the FPCA and the second end of the FPCA are adjacent to one another, a body connected to the frame and applying a compressive force to the FPCA between the body and the frame, a display cover positioned between at least a portion of the body and the display module, and a gasket positioned between the display module and the display cover, wherein the gasket is at least 10% compressed by the compressive force.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

1. A display device comprising:
a flexible printed circuit assembly (FPCA) including:
a display module located at a first end of the FPCA, and
an input device located at a second end of the FPCA opposite the first end, wherein the input device includes a contact sensor configured to detect a user's press on the input device; and
a frame supporting the FPCA, wherein the FPCA is wrapped around the frame where the first end of the FPCA and the second end of the FPCA are adjacent to one another.

2. The display device of claim 1, further comprising a display controller integrated into the display module.

3. The display device of claim 1, further comprising a flexible connector configured to provide electrical communication to the display module and the input device, wherein the flexible connector is connected to the FPCA at a T-junction between the first end and the second end.

4. The display device of claim 3, wherein the T-junction is located in a center 50% of a length of the FPCA between the first end and the second end.

5. The display device of claim 4, wherein the T-junction is located equidistant from the first end and the second end.

6. The display device of claim 4, wherein the T-junction is located closer to the first end than the second end.

7. The display device of claim 3, wherein the FPCA includes no signal handling components in an electrical trace between the display module and the flexible connector.

8. The display device of claim 1, further comprising a display cover that covers both the display module and the input device.

9. The display device of claim 8, wherein the display cover presents a dead front when the display module is not illuminated.

10. The display device of claim 8, further comprising an input button that is movable relative to a body of the display device and configured to transmit a force to the input device.

11. The display device of claim 10, wherein the input button is a discrete input button that is movable relative to the display cover.

12. The display device of claim 10, wherein the input button is an integrated input button integrated into the display cover.

13. The display device of claim 8, further comprising a grounding element positioned between the display cover and at least a portion of the FPCA.

14. The display device of claim 13, wherein the grounding element is electrically connected to a wired connection port.

15. An electronic device controller comprising:
one or more face buttons supported on a face surface;
one or more directional input devices on the face surface; and
a display device including:
a flexible printed circuit assembly (FPCA) including:
a display module located at a first end of the FPCA, and
an input device located at a second end of the FPCA opposite the first end, wherein the input device includes a contact sensor configured to detect a user's press on the input device, and
a frame supporting the FPCA, wherein the FPCA is wrapped around the frame where the first end of the FPCA and the second end of the FPCA are adjacent to one another.

16. The electronic device controller of claim 15, wherein the display device is located on a front surface of the electronic device controller.

17. The electronic device controller of claim 15, wherein the display device is configured to display controller information.

18. The electronic device controller of claim 15, further comprising a wireless communication device and wherein the display device is configured to display a wireless connection mode.

19. The electronic device controller of claim 15, further comprising a wired connection port, and wherein the display device further including a grounding element electrically connected to the wired connection port.

20. An electronic device controller comprising:
one or more face buttons supported on a face surface;
one or more directional input devices on the face surface; and
a display device located on a front surface, the display device including:
a flexible printed circuit assembly (FPCA) including:
a display module located at a first end of the FPCA, and
an input device located at a second end of the FPCA opposite the first end, wherein the input device includes a contact sensor configured to detect a user's press on the input device,
a frame supporting the FPCA, wherein the FPCA is wrapped around the frame where the first end of the FPCA and the second end of the FPCA are adjacent to one another,
a body connected to the frame and applying a compressive force to the FPCA between the body and the frame,
a display cover positioned between at least a portion of the body and the display module, and
a gasket positioned between the display module and the display cover, wherein the gasket is at least 10% compressed by the compressive force.
